(19) United States
(12) Patent Application Publication
(10) Pub. No.: US 2023/0380203 A1
(43) Pub. Date: Nov. 23, 2023

(54) QUANTUM DOT LIGHT-EMITTING DEVICE, DISPLAY APPARATUS AND MANUFACTURING METHOD

(71) Applicant: BOE Technology Group Co., Ltd., Beijing (CN)

(72) Inventor: Jingwen FENG, Beijing (CN)

(21) Appl. No.: 18/028,335

(22) PCT Filed: Jan. 26, 2021
(86) PCT No.: PCT/CN2021/073857

§ 371 Date: Mar. 24, 2023

(51) Int. Cl. H10K 50/115; H10K 71/10; C09K 11/06

(52) U.S. Cl. CPC H10K 50/115; H10K 71/10; C09K 11/06; C09K 2211/10; H10K 85/381

(57) ABSTRACT

Provided are a quantum dot light-emitting device, a display apparatus and a manufacturing method The quantum dot light-emitting device includes: a light-emitting layer group of a first and second quantum dot light-emitting layers arranged in a laminated manner, the chain length of a first ligand is greater than that of a second ligand, the difference between two chain lengths is greater than a first preset value; the difference between the number of carriers arriving at the light-emitting layer group from a first electrode layer and the number of carriers arriving at the light-emitting layer group from a second electrode layer is greater than a second preset value; the side of the light-emitting layer group with the largest number of entering carriers is used as a multi-carrier entry side; the first quantum dot light-emitting layer is on the surface of the second quantum dot light-emitting layer facing the multi-carrier entry side.

### CROSS-REFERENCE TO RELATED APPLICATIONS

This application is a National Stage of International Application No. PCT/CN2021/073857, filed Jan. 26, 2021 which is hereby incorporated by reference in its entirety.

### FIELD

The present disclosure relates to the technical field of semiconductors, in particular to quantum dot light-emitting device, a display apparatus and a manufacturing method.

### BACKGROUND

With the development of quantum dot materials, constant optimization of device structures, and ongoing research on efficient charge transport, Quantum Dot light-emitting Diodes (QLED) display will surpass photoluminescent quantum dot brightness enhancement films and quantum dot color filters, and is expected to become the next generation of mainstream display technology.

### SUMMARY

An embodiment of the present disclosure provides a quantum dot light-emitting device, including: a base substrate; a first electrode layer, located on one side of the base substrate; a second electrode layer, located on one side of the first electrode layer facing away from the base substrate; a light-emitting layer group, located between the first electrode layer and the second electrode layer, and including a first quantum dot light-emitting layer and a second quantum dot light-emitting layer disposed in a lamination manner, wherein the first quantum dot light-emitting layer includes a first quantum dot body, and a first ligand connected to the first quantum dot body; the second quantum dot light-emitting layer includes a second quantum dot body, and a second ligand connected to the second quantum dot body; the chain length of the first ligand is greater than the chain length of the second ligand, and a difference between the two chain lengths is greater than a first preset value; a difference between the quantity of carriers arriving at the light-emitting layer group from the first electrode layer and the quantity of carriers arriving at the light-emitting layer group from the second electrode layer is greater than a second preset value; and one side of the light-emitting layer group with a great quantity of incoming carriers serves as a multi-carrier entry side, and the first quantum dot light-emitting layer is located on one surface of the second quantum dot light-emitting layer facing the multi-carrier entry side.

In a possible embodiment, the first ligand includes one of: trioctylphosphine, tributylphosphine, oleic acid, stearic acid; oleylamine, long-chain alkylamine, long-chain alkylphosphine, or long-chain alkylphosphonic acid.

In a possible embodiment, the second ligand includes one of: thiol, dithiol, mercapto acid, mercaptoalcohol. Mercaptoamine, or a halogen ligand.

In a possible embodiment, the thickness of the first quantum dot light-emitting layer is in positive correlation with the second preset value.

In a possible embodiment, the quantity of carriers arriving at the light-emitting layer group from the first electrode layer is greater than the quantity of carriers arriving at the light-emitting layer group from the second electrode layer. One side of the light-emitting layer group facing the first electrode layer serves as the multi-carrier entry side.

The first quantum dot light-emitting layer is located on one side of the second quantum dot light-emitting layer facing the first electrode layer.

In a possible embodiment, the quantity of carriers arriving at the light-emitting layer group from the first electrode layer is less than the quantity of carriers arriving at the light-emitting layer group from the second electrode layer. One side of the light-emitting layer group facing the second electrode layer serves as the multi-carrier entry side.

The first quantum dot light-emitting layer is located on one side of the second quantum dot light-emitting layer facing the second electrode layer.

In a possible embodiment, the first quantum dot body is the same as the second quantum dot body.

In a possible embodiment, the first quantum dot light-emitting layer includes at least one first sub-quantum dot light-emitting layer disposed in a lamination manner. The first ligand of each first sub-quantum dot light-emitting layer is the same, and the first quantum dot body is the same.

The second quantum dot light-emitting layer includes at least one second sub-quantum dot light-emitting layer disposed in a lamination manner. The second ligand of each second sub-quantum dot light-emitting layer is the same, and the second quantum dot body is the same.

An embodiment of the present disclosure also provides a display apparatus, including the quantum dot light-emitting device as provided by the embodiment of the present disclosure.

An embodiment of the present disclosure further provides a manufacturing method of the quantum dot light-emitting device as provided by the embodiment of the present disclosure, including: forming a first electrode layer on one side of a base substrate; forming a light-emitting layer group on one side of the first electrode layer facing away from the base substrate, wherein the light-emitting layer group includes a first quantum dot light-emitting layer and a second quantum dot light-emitting layer disposed in a lamination manner; the first quantum dot light-emitting layer includes a first quantum dot body, and a first ligand connected to the first quantum dot body; the second quantum dot light-emitting layer includes a second quantum dot body, and a second ligand connected to the second quantum dot body; the first quantum dot body is the same as the second quantum dot body; the chain length of the first ligand is greater than the chain length of the second ligand, and a difference between the two chain lengths is greater than a first preset value; and forming a second electrode layer on one side of the light-emitting layer group facing away from the first electrode layer, wherein a difference between the quantity of carriers arriving at the light-emitting layer group from the first electrode layer and the quantity of carriers arriving at the light-emitting layer group from the second electrode layer group is greater than a second preset value; one side of the light-emitting layer group with a great quantity of incoming carriers serves as a multi-carrier entry side, and the first quantum dot light-emitting layer is located on one surface of the second quantum dot light-emitting layer facing the multi-carrier entry side.

In a possible embodiment, when the quantity of carriers arriving at the light-emitting layer group from the first electrode layer is greater than the quantity of carriers arriving at the light-emitting layer group from the second electrode layer, forming the light-emitting layer group on one side of the first electrode layer facing away from the base substrate includes: forming the first quantum dot light-emitting layer on one side of the first electrode layer facing away from the base substrate; and forming the second quantum dot light-emitting layer on one side of the first quantum dot light-emitting layer facing away from the first electrode layer.

In a possible embodiment, forming the first quantum dot light-emitting layer on one side of the first electrode layer facing away from the base substrate; and forming the second quantum dot light-emitting layer on one side of the first quantum dot light-emitting layer facing away from the first electrode layer, include: forming a first quantum dot solution in which the first ligand modifies the first quantum dot body, and a second quantum dot solution in which a third ligand modifies the second quantum dot body; replacing, in a solution state, the third ligand in the second quantum dot solution with a second ligand by a replacement reaction to form a third quantum dot solution in which the second ligand modifies the second quantum dot body, wherein the chain length of the third ligand is greater than the chain length of the second ligand; overlaying the first quantum dot solution on one side of the first electrode layer facing away from the base substrate to serve as the first quantum dot light-emitting layer; and overlaying the third quantum dot solution on one side of the first quantum dot light-emitting layer facing away from the first electrode layer to serve as the second quantum dot light-emitting layer.

In a possible embodiment, forming the first quantum dot light-emitting layer on one side of the first electrode layer facing away from the base substrate; and forming the second quantum dot light-emitting layer on one side of the first quantum dot light-emitting layer facing away from the first electrode layer, include: forming a first quantum dot solution in which the first ligand modifies the first quantum dot body, and a second quantum dot solution in which a third ligand modifies the second quantum dot body; overlaying the first quantum dot solution on one side of the first electrode layer facing away from the base substrate to serve as the first quantum dot light-emitting layer; and overlaying the second quantum dot solution on one side of the first quantum dot light-emitting layer facing away from the first electrode layer, and overlaying a solution containing the second ligand after film formation to replace the third ligand with the second ligand to serve as the second quantum dot light-emitting layer.

In a possible embodiment, when the quantity of carriers arriving at the light-emitting layer group from the first electrode layer is less than the quantity of carriers arriving at the light-emitting layer group from the second electrode layer, forming the light-emitting layer group on one side of the first electrode layer facing away from the base substrate includes: forming the second quantum dot light-emitting layer on one side of the first electrode layer facing away from the base substrate; and forming the first quantum dot light-emitting layer on one side of the second quantum dot light-emitting layer facing away from the first electrode layer.

In a possible embodiment, forming the second quantum dot light-emitting layer on one side of the first electrode layer facing away from the base substrate; and forming the first quantum dot light-emitting layer on one side of the second quantum dot light-emitting layer facing away from the first electrode layer, include: forming a first quantum dot solution in which the first ligand modifies the first quantum dot body, and a second quantum dot solution in which a third ligand modifies the second quantum dot body; overlaying the second quantum dot solution on one side of the first electrode layer facing away from the base substrate and overlaying a solution containing the second ligand after film formation to replace the third ligand with the second ligand to serve as the second quantum dot light-emitting layer; and overlaying the first quantum dot solution on one side of the second quantum dot light-emitting layer facing away from the first electrode layer.

### BRIEF DESCRIPTION OF THE DRAWINGS

FIG. 1 is a schematic structural diagram of a quantum dot light-emitting device according to an embodiment of the present disclosure;

FIG. 2 is an enlarged view of a quantum dot light-emitting layer according to an embodiment of the present disclosure;

FIG. 3 is a schematic structural diagram of a quantum dot light-emitting device with more carriers injected from a first electrode layer according to an embodiment of the present disclosure;

FIG. 4 is a schematic structural diagram of a quantum dot light-emitting device with more carriers injected from a second electrode layer according to an embodiment of the present disclosure;

FIG. 5 is a schematic structural diagram of a specific quantum dot light-emitting device according to an embodiment of the present disclosure;

FIG. 6 is a flow chart illustrating the manufacturing of a quantum dot light-emitting device according to an embodiment of the present disclosure; and

FIG. 7 is a schematic structural diagram of another quantum dot light-emitting device according to an embodiment of the present disclosure.

### DETAILED DESCRIPTION OF THE EMBODIMENTS

In order to make the objectives, technical solutions and advantages of embodiments of the present disclosure clearer, the technical solutions of the embodiments of the present disclosure will be clearly and completely described below in conjunction with the accompanying drawings of the embodiments of the present disclosure. Apparently, the described embodiments are some, but not all, embodiments of the present disclosure. Based on the described embodiments of the present disclosure, other embodiments obtained by a person of ordinary skill in the art without inventive effort all fall within the scope of protection of the present disclosure.

Unless otherwise defined, technical terms or scientific terms used herein shall have the ordinary meaning understood by a person of ordinary skill in the art to which the present disclosure belongs. “First,” “second,” and other similar words used in the present disclosure do not denote any order, quantity, or importance, but are merely used to distinguish different components. “Include”, “comprise” and other similar words mean that an element or an item preceding the word encompasses an element or an item listed behind the word without excluding other elements or items. “connect”, “link” and other similar words are not restricted to physical or mechanical connections, but can include electrical connections, whether direct or indirect. The “upper”, “lower”, “left”, “right” and the like are only used for representing the relative position relation, and when the absolute position of the described object is changed, the relative position relation can also be correspondingly changed.

Current QLED devices tend to have the problem of unbalanced injection of electrons and holes, and the electrons and holes are likely to become multi-carriers in the QLED devices according to differences in device structure and functional layer material used. Carrier imbalance in the device generally leads to quantum dot charging and thus leads to occurrence of non-radiative recombination to affect the efficiency of the QLED devices, and in addition can lead to shortened QLED device lifetime.

To keep the clear and concise description of the embodiments of the present disclosure below, the present disclosure omits detailed descriptions of known functions and known components.

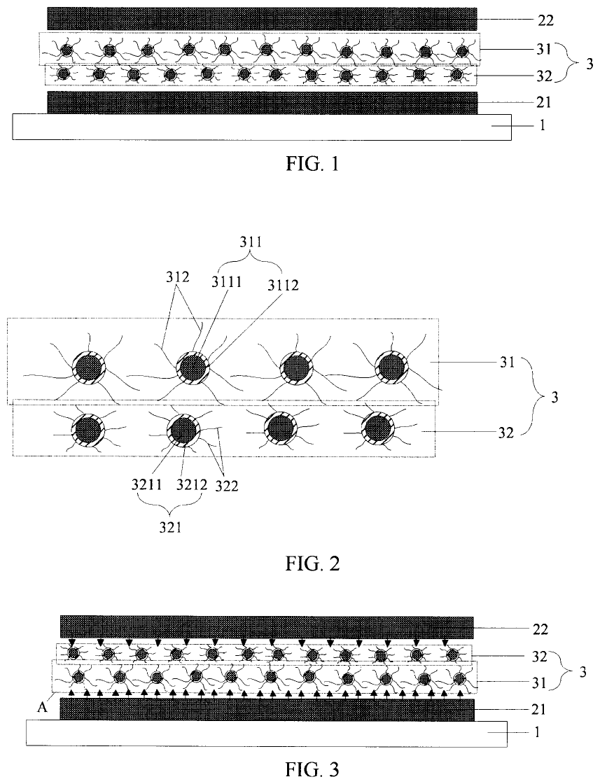

An embodiment of the present disclosure provides a quantum dot light-emitting device, as shown in FIG. 1 and FIG. 2, including:
a base substrate 1;
a first electrode layer 21, located on one side of the base substrate 1;
a second electrode layer 22, located on one side of the first electrode layer 21 facing away from the base substrate 1;
a light-emitting layer group 3, located between the first electrode layer 21 and the second electrode layer 22, and including a first quantum dot light-emitting layer 31 and a second quantum dot light-emitting layer 32 disposed in a lamination manner, wherein the first quantum dot light-emitting layer 31 includes a first quantum dot body 311, and a first ligand 312 connected to the first quantum dot body 311; the second quantum dot light-emitting layer 32 includes a second quantum dot body 321, and a second ligand 322 connected to the second quantum dot body 321; the chain length of the first ligand 312 is greater than the chain length of the second ligand 322, and a difference between the two chain lengths is greater than a first preset value; a difference (specifically, the difference can be understood as the absolute value of the difference) between the quantity of carriers arriving at the light-emitting layer group 3 from the first electrode layer 21 and the quantity of carriers arriving at the light-emitting layer group 3 from the second electrode layer 22 is greater than a second preset value; and one side of the light-emitting layer group 3 with a great quantity of incoming carriers serves as a multi-carrier entry side, and the first quantum dot light-emitting layer 31 is located on one surface of the second quantum dot light-emitting layer 32 facing the multi-carrier entry side. In some embodiments, the first quantum dot body 311 is the same as the second quantum dot body 321. The first quantum dot body 311 is of a core-shell structure formed by a first quantum dot core 3111 and a first shell 3112 encapsulating the first quantum dot core 3111. Similarly, the second quantum dot body 321 is of a core-shell structure formed by a second quantum dot core 3211 and a second shell 3212 encapsulating the second quantum dot core 3211. For the first preset value, it can be understood that the difference between the chain lengths of the first ligand 312 and the second ligand 322 needs to reach a set quantity so as to achieve appreciably different carrier transport effects. Specifically, the first preset value can be the difference quantity of carbon atoms, which, for example, may be 8-15. For the second preset value, it can be understood that when the difference between the quantity of carriers arriving at the light-emitting layer group 3 from the first electrode layer 21 (arriving at the light-emitting layer group 3, but not entering the light-emitting layer group 3, i.e., before being regulated by ligands with different chain lengths), and the quantity of carriers arriving at the light-emitting layer group 3 from the second electrode layer 22 is greater than this value, it is considered that the light-emitting device suffers from a significant carrier injection imbalance problem, and thus there is a need for regulation. When the difference between the quantity of carriers arriving at the light-emitting layer group 3 from the first electrode layer 21 and the quantity of carriers arriving at the light-emitting layer group 3 from the second electrode layer 22 is less than this value, it is considered that no significant carrier injection imbalance problem occurs in the light-emitting device, for example, when the difference is 1, the difference quantity is small, it is considered that no significant carrier injection imbalance problem occurs in the light-emitting device, and there is no need for regulation. The second preset value may be obtained from empirical data or experimentation when in specific implementation.

In an embodiment of the present disclosure, the light-emitting layer group 3 includes a first quantum dot light-emitting layer 31 and a second quantum dot light-emitting layer 32 disposed in a lamination manner. The chain length of a first ligand 312 of the first quantum dot light-emitting layer 31 is greater than the chain length of a second ligand 322 of the second quantum dot light-emitting layer 32. The first quantum dot light-emitting layer 31 is located on one surface of the second quantum dot light-emitting layer 32 facing a multi-carrier entry side A, that is, electrons and holes can be prevented from injection using the characteristic of poor electron or hole transport performance of the long-chain ligand by applying quantum dots with long-chain ligands and short-chain ligands respectively in the light-emitting device, and then a first quantum dot light-emitting layer with a long-chain ligand may be disposed on the side where more carriers (electrons or holes) are injected, reducing the injection of carriers on this side. Meanwhile, in order to avoid blocking the injection of carriers on the other side by the first quantum dot light-emitting layer with the long-chain ligand, a second quantum dot light-emitting layer with a short-chain ligand may be provided, and the second quantum dot light-emitting layer with the short-chain ligand facilitates injection of carriers, so that the first quantum dot light-emitting layer and the second quantum dot light-emitting layer can be used to block the injection at the side where more carriers are injected, and to increase the injection at the side where fewer carriers are injected, so as to regulate the injection of electrons and holes, thereby achieving injection balance of carriers.

In some embodiments, as shown in FIG. 3, for example, the quantity of carriers arriving at the light-emitting layer group 3 from the first electrode layer 21 is greater than the quantity of carriers arriving at the light-emitting layer group 3 from the second electrode layer 22. In FIG. 3, the density of arrows indicates the quantity of carriers injected, wherein the denser arrows indicate more carriers injected, and the sparser arrows indicate less carriers injected. One side of the light-emitting layer group 3 facing the first electrode layer 21 serves as the multi-carrier entry side A. The first quantum dot light-emitting layer 31 is located on one side of the second quantum dot light-emitting layer 32 facing the first electrode layer 21.

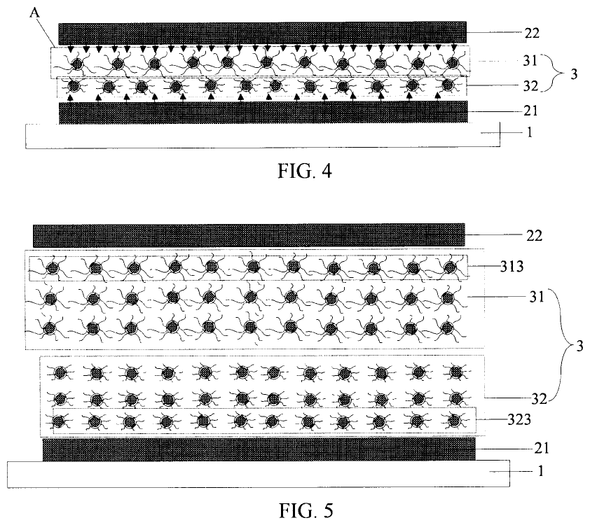

For another example, as shown in FIG. 4, the quantity of carriers arriving at the light-emitting layer group 3 from the first electrode layer 21 is less than the quantity of carriers arriving at the light-emitting layer group from the second electrode layer. In FIG. 4, the density of arrows indicates the quantity of carriers injected, wherein the denser arrows indicate more carriers injected, and the sparser arrows indicate less carriers injected. One side of the light-emitting layer group 3 facing the second electrode layer 22 serves as the multi-carrier entry side A. The first quantum dot light-emitting layer 31 is located on one side of the second quantum dot light-emitting layer 32 facing the second electrode layer 22.

In some embodiments, functional layers may be further disposed in the quantum dot light-emitting device, for example, may include a hole injection layer, a hole transport layer and an electron transport layer. In a multi-electron system (i.e., the injection quantity of electron is greater than the injection quantity of holes), the injection of electrons needs to be limited in order to achieve electron-hole balance. Therefore, the first quantum dot light-emitting layer 31 with the long-chain ligand needs to be in contact with the electron transport layer, and the second quantum dot light-emitting layer 32 with the short-chain ligand needs to be in contact with the hole transport layer. The light-emitting device may specifically include an upright structure, an inverted structure, a top emission structure and a bottom emission structure. For example, the light-emitting device may be of an upright bottom emission structure: an anode (the material may be indium tin oxide, ITO, specifically)/a hole injection layer (HI)/a hole transport layer (HT)/a second quantum dot light-emitting layer with a short-chain ligand/a first quantum dot light-emitting layer with a long-chain ligand/an electron transport layer (ET)/a cathode (the material may be Al specifically). For example, the light-emitting device may be of an inverted bottom emission structure: a cathode (the material may be indium tin oxide, ITO, specifically)/an electron transport layer (ET)/a first quantum dot light-emitting layer with a long-chain ligand/a second quantum dot light-emitting layer with a short-chain ligand/a hole transport layer (HT)/a hole injection layer (HI)/anode (the material may be Ag specifically). For example, the light-emitting device may be of an upright top emission structure: an anode (the material may be ITO/Ag/ITO specifically)/a hole injection layer (HI)/a hole transport layer (HT)/a second quantum dot light-emitting layer with a short-chain ligand/a first quantum dot light-emitting layer with a long-chain ligand/an electron transport layer (ET)/a cathode (the material may be indium zinc oxide, IZO, specifically). For example, the light-emitting device may be of an inverted top emission structure: a cathode (the material may be ITO/Ag/ITO specifically)/an electron transport layer (ET)/a first quantum dot light-emitting layer with a long-chain ligand/a second quantum dot light-emitting layer with a short-chain ligand/a hole transport layer (HT)/a hole injection layer (HI)/anode (the material may be Ag specifically).

Likewise, in a multi-hole system (i.e., the injection quantity of holes is greater than the injection quantity of electrons), the injection of holes needs to be limited in order to achieve electron-hole balance. Therefore, the first quantum dot light-emitting layer with the long-chain ligand needs to be in contact with the hole transport layer, and the second quantum dot light-emitting layer with the short-chain ligand needs to be in contact with the electron transport layer. The light-emitting device may specifically include an upright structure, an inverted structure, a top emission structure and a bottom emission structure. For example, the light-emitting device may be of an upright bottom emission structure: an anode (the material may be indium tin oxide, ITO, specifically)/a hole injection layer (HI)/a hole transport layer (HT)/a first quantum dot light-emitting layer with a long-chain ligand/a second quantum dot light-emitting layer with a short-chain ligand/an electron transport layer (ET)/a cathode (the material may be Al specifically). For example, the light-emitting device may be of an inverted bottom emission structure: a cathode (the material may be indium tin oxide, ITO, specifically)/an electron transport layer (ET)/a second quantum dot light-emitting layer with a short-chain ligand/a first quantum dot light-emitting layer with a long-chain ligand/a hole transport layer (HT)/a hole injection layer (HI)/anode (the material may be Ag specifically). For example, the light-emitting device may be of an upright top emission structure: an anode (the material may be ITO/Ag/ITO specifically)/a hole injection layer (HI)/a hole transport layer (HT)/a first quantum dot light-emitting layer with a long-chain ligand/a second quantum dot light-emitting layer with a short-chain ligand/an electron transport layer (ET)/a cathode (the material may be indium zinc oxide, IZO, specifically). For example, the light-emitting device may be of an inverted top emission structure: a cathode (the material may be ITO/Ag/ITO specifically)/an electron transport layer (ET)/a second quantum dot light-emitting layer with a short-chain ligand/a first quantum dot light-emitting layer with a long-chain ligand/a hole transport layer (HT)/a hole injection layer (HI)/an anode (the material may be Ag specifically).

In some embodiments, a light-emitting device with different chain lengths of ligands, which is required to be set, can be empirically determined, or is subjected to experimentation in advance to determine whether the light-emitting device is a multi-hole system or a multi-electron system. For example, in an example that an original light-emitting device structurally includes a first electrode layer, a hole injection layer, a hole transport layer, a light-emitting layer, an electron transport layer, and a second electrode layer, which are disposed in sequence, a single electronic device (being of a specific structure: a first electrode layer, an electron transport layer, a light-emitting layer, an electron transport layer, a second electrode layer in sequence) and a single hole device (being of a specific structure: a first electrode layer, a hole injection layer, a hole transport layer, a light-emitting layer, and a second electrode layer in sequence) may be provided, and the current-voltage curves of the single electronic device, and the single hole device are tested respectively. Comparison is made under the same voltage, if the current of the single electronic device is higher, it is determined that the original light-emitting device is the multi-electron system, and if the current of the single hole device is higher, it is determined that the original light-emitting device is the multi-hole device.

In some embodiments, the first ligand 312 may include one of:
trioctylphosphine; tributylphosphine; oleic acid; stearic acid; oleylamine; long-chain alkylamine; long-chain alkylphosphine; or long-chain alkylphosphonic acid.

In some embodiments, the second ligand 322 includes one of:
thiol; dithiol; mercapto acid; mercaptoalcohol; mercaptoamine; or a halogen ligand.

In some embodiments, the thickness of the first quantum dot light-emitting layer 31 is in positive correlation with the second preset value. In the embodiment of the present disclosure, the thicker the first quantum dot light-emitting layer 31 is, the stronger the blocking effect on electrons and holes is, so that the thickness of the first quantum dot light-emitting layer 31 is in positive correlation with the second preset value, the carrier injection balance can be further controlled by regulating the thickness of the first quantum dot light-emitting layer 31.

In some embodiments, as shown in FIG. 5, the first quantum dot light-emitting layer 31 may include at least one first sub-quantum dot light-emitting layer 313 disposed in a lamination manner, wherein first ligands 312 of the individual first sub-quantum dot light-emitting layers 313 are the same, and first quantum dot bodies 311 are the same. The second quantum dot light-emitting layer 32 includes at least one second sub-quantum dot light-emitting layer 323 disposed in a lamination manner, wherein second ligands 322 of the individual second sub-quantum dot light-emitting layers 323 are the same, and second quantum dot bodies 321 are the same.

Based on the same inventive concept, an embodiment of the present disclosure also provides a display apparatus including the quantum dot light-emitting device as provided by the embodiment of the present disclosure.

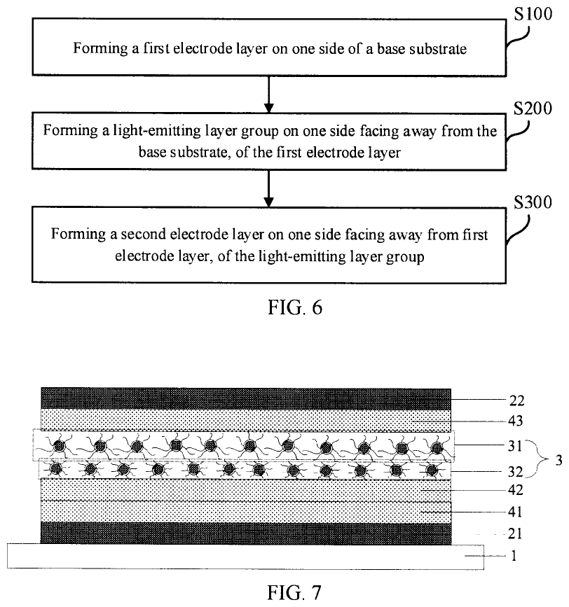

Based on the same inventive concept, an embodiment of the present disclosure also provides a manufacturing method of the quantum dot light-emitting device as provided by the embodiment of the present disclosure, as shown in FIG. 6, including:
step S100, forming a first electrode layer on one side of a base substrate;
step S200, forming a light-emitting layer group on one side of the first electrode layer facing away from the base substrate, wherein the light-emitting layer group includes a first quantum dot light-emitting layer and a second quantum dot light-emitting layer disposed in a lamination manner, the first quantum dot light-emitting layer includes a first quantum dot body, and a first ligand connected to the first quantum dot body, the second quantum dot light-emitting layer includes a second quantum dot body, and a second ligand connected to the second quantum dot body, the first quantum dot body is the same as the second quantum dot body, the chain length of the first ligand is greater than the chain length of the second ligand, and the difference between the two chain lengths is greater than a first preset value; and
step S300, forming a second electrode layer on one side of the light-emitting layer group facing away from the first electrode layer, wherein a difference between the quantity of carriers arriving at the light-emitting layer group from the first electrode layer and the quantity of carriers arriving at the light-emitting layer group from the second electrode layer group is greater than a second preset value, one side of the light-emitting layer group with a great quantity of incoming carriers serves as a multi-carrier entry side, and the first quantum dot light-emitting layer is located on one surface of the second quantum dot light-emitting layer facing the multi-carrier entry side.

In some embodiments, in combination with FIG. 3, when the quantity of carriers arriving at the light-emitting layer group from the first electrode layer is greater than the quantity of carriers arriving at the light-emitting layer group from the second electrode layer, step S200 of forming the light-emitting layer group on one side of the first electrode layer facing away from the base substrate includes:
forming a first quantum dot light-emitting layer on one side of the first electrode layer facing away from the base substrate; and
forming a second quantum dot light-emitting layer on one side of the first quantum dot light-emitting layer facing away from the first electrode layer.

In some embodiments, for formation of a light-emitting device with a structure shown in FIG. 3, a second quantum dot light-emitting layer with a short-chain ligand can be formed by thin film ligand exchange and solution ligand exchange, as illustrated by the following example.

For example, a second quantum dot light-emitting layer with a short-chain ligand is formed by solution ligand exchange. In some embodiments, the above steps of forming the first quantum dot light-emitting layer on one side of the first electrode layer facing away from the base substrate; and forming the second quantum dot light-emitting layer on one side of the first quantum dot light-emitting layer facing away from the first electrode layer may include:
forming a first quantum dot solution in which a first ligand modifies a first quantum dot body, and a second quantum dot solution in which a third ligand modifies a second quantum dot body, wherein the third ligand may be the same as or different from the first ligand;
replacing, in a solution state, the third ligand in the second quantum dot solution with a second ligand by a replacement reaction to form a third quantum dot solution in which the second ligand modifies the second quantum dot body, wherein the chain length of the third ligand is greater than the chain length of the second ligand;
overlaying the first quantum dot solution on one side of the first electrode layer facing away from the base substrate to serve as the first quantum dot light-emitting layer; and
overlaying the third quantum dot solution on one side of the first quantum dot light-emitting layer facing away from the first electrode layer to serve as the second quantum dot light-emitting layer.

For another example, a second quantum dot light-emitting layer with a short-chain ligand is formed by thin film ligand exchange. In some embodiments, the above steps of forming the first quantum dot light-emitting layer on one side of the first electrode layer facing away from the base substrate; and forming the second quantum dot light-emitting layer on one side of the first quantum dot light-emitting layer facing away from the first electrode layer may include:
forming a first quantum dot solution in which a first ligand modifies a first quantum dot body, and a second quantum dot solution in which a third ligand modifies a second quantum dot body;
overlaying the first quantum dot solution on one side of the first electrode layer facing away from the base substrate to serve as the first quantum dot light-emitting layer; and
overlaying the second quantum dot solution on one side of the first quantum dot light-emitting layer facing away from the first electrode layer, and overlaying a solution containing the second ligand after film formation to replace the third ligand with the second ligand to serve as the second quantum dot light-emitting layer.

In some embodiments, in combination with FIG. 4, when the quantity of carriers arriving at the light-emitting layer group from the first electrode layer is less than the quantity of carriers arriving at the light-emitting layer group from the second electrode layer, forming the light-emitting layer group on one side of the first electrode layer facing away from the base substrate includes:
forming a second quantum dot light-emitting layer on one side of the first electrode layer facing away from the base substrate; and
forming a first quantum dot light-emitting layer on one side of the second quantum dot light-emitting layer facing away from the first electrode layer.

In some embodiments, a second quantum dot light-emitting layer with a short-chain ligand is formed by solution ligand exchange. In some embodiments, for formation of a light-emitting device with a structure shown in FIG. 4, a second quantum dot light-emitting layer with a short-chain ligand can be formed by thin film ligand exchange, as illustrated by the following example.

For example, a second quantum dot light-emitting layer with a short-chain ligand is formed by thin film ligand exchange. In some embodiments, the above steps of forming the second quantum dot light-emitting layer on one side of the first electrode layer facing away from the base substrate; and forming the first quantum dot light-emitting layer on one side of the second quantum dot light-emitting layer facing away from the first electrode layer may include:
forming a first quantum dot solution in which a first ligand modifies a first quantum dot body, and a second quantum dot solution in which a third ligand modifies a second quantum dot body;
overlaying the second quantum dot solution on one side of the first electrode layer facing away from the base substrate and overlaying a solution containing the second ligand after film formation to replace the third ligand with the second ligand to serve as the second quantum dot light-emitting layer; and
overlaying the first quantum dot solution on one side of the second quantum dot light-emitting layer facing away from the first electrode layer.

In some embodiments of the present disclosure, when in formation of the second quantum dot light-emitting layer with the short-chain ligand, the first quantum dot light-emitting layer with the long-chain ligand may be formed first, and then the long-chain ligand may be replaced with the short-chain ligand by ligand replacement, thereby avoiding the problems that quantum dots are prone to agglomeration to result in difficulty in film formation if the second quantum dot light-emitting layer with the short-chain ligand is directly formed.

In order to more clearly understand the manufacturing method of the quantum dot light-emitting device provided by embodiments of the present disclosure, the further description is made as follows.

I. Solution Ligand Exchange.

(a) Quantum Dots with Long-Chain/Short-Chain Preparation.

Quantum dots include but are not limited to CdS/ZnS, CdSe/ZnS, InP/ZnS, PbS/ZnS, CsPbCl3/ZnS, CsPbBr3/ZnS, CsPbI3/ZnS, CdS/ZnS, CdSe/ZnS, CdS@ZnSZnS, CdSe/ZnS, InP/ZnS/ZnO, PbS/ZnS, CsPbCl3/ZnS, CsPbBr3/ZnS, CsPbI3/ZnS, CdS/ZnS, CdSe/ZnS, ZnTe/ZnSe/ZnS, ZnSeTe/ZnSe/ZnS, and a preparation method thereof is consistent with a common quantum dots synthesis method.
1. Quantum dots with long-chain ligands are prepared by a traditional quantum dot synthesis method.
2. Quantum dots with short-chain ligands can be prepared by ligand exchange in solution. Taking CdSe/ZnS quantum dots with oleic acid ligands as an example, a method for replacing CdSe/ZnS quantum dots with oleic acid ligands with quantum dots with short-chain halogen ligands is as follows:

CdSe/ZnS quantum dots with long-chain oleic acid ligands prepared using a conventional method are subjected to centrifugal washing with ethanol, supernatant removal is performed, then the quantum dots are re-dispersed in octane, a ZnCl₂ solution dissolved with ethanol is added into the quantum dot colloid, and stirred reaction is carried out for 1 h at 80° C. for ligand exchange.

(b) Preparation of a QLED Device.

Taking a multi-electron QLED device system as an example, a hole injection layer is prepared using a spin coating process, for example, spin coating is carried out on a hole injection material such as PEDOT:PSS. Then, spin coating is carried out on the hole transport layer, the quantum dots with the short-chain ligands (prepared by the above method), quantum dots with long-chain ligands, and the electron transport layer. Subsequently, cathode metal is subjected to evaporation, wherein the cathode may employ an Al layer or the like, which is about 500-1000 nm. Encapsulation is carried out after evaporation to complete the preparation of the QLED device. The quantum dots with the short-chain ligands and the quantum dots with the long-chain ligands can be prepared as a one-layer structure or a multi-layer structure, respectively. This method can precisely control the thicknesses of the quantum dots with the long-chain ligands and the quantum dots with short-chain ligands by adjusting the spin coating concentration and velocity of the quantum dots with the long-chain ligands and the quantum dots with the short-chain ligands, which is advantageous for regulating the carrier balance.

Taking a multi-hole QLED device system as an example, a hole injection layer is prepared using a spin coating process, for example, spin coating is carried out on a hole injection material such as PEDOT:PSS. Then, spin coating is carried out on the hole transport layer, the quantum dots with the long-chain ligands (prepared by the above method), quantum dots with shot-chain ligands, and the electron transport layer. Subsequently, cathode metal is subjected to evaporation, wherein the cathode may employ an Al layer or the like, which is about 500-1000 nm. Encapsulation is carried out after evaporation to complete the preparation of the QLED device. The quantum dots with the short-chain ligands and the quantum dots with the long-chain ligands can be prepared as a one-layer structure or a multi-layer structure, respectively. This method can precisely control the thicknesses of the quantum dots with the long-chain ligands and the quantum dots with short-chain ligands by adjusting the spin coating concentration and velocity of the quantum dots with the long-chain ligands and the quantum dots with the short-chain ligands, which is advantageous for regulating the carrier balance.

II. Membrane Ligand Exchange.

(a) Preparation of Quantum Dots with Long-Chain Ligands.

In this patent, quantum dots include but are not limited to CdS/ZnS, CdSe/ZnS, InP/ZnS, PbS/ZnS, CsPbCl3/ZnS, CsPbBr3/ZnS, CsPbI3/ZnS, CdS/ZnS, CdSe/ZnS, CdS@ZnSZnS, CdSe/ZnS, InP/ZnS/ZnO, PbS/ZnS, CsPbCl3/ZnS, CsPbBr3/ZnS, CsPbI3/ZnS, CdS/ZnS, CdSe/ZnS, ZnTe/ZnSe/ZnS, ZnSeTe/ZnSe/ZnS. A preparation method thereof is consistent with a common quantum dot synthesis method.

(b) Preparation of a QLED Device (Including Thin Film Ligand Exchange).

Taking a multi-hole QLED device system as an example, the hole injection layer is prepared using a spin coating process, for example, spin coating is carried out on a hole injection material such as PEDOT:PSS. Spin coating is carried out on the hole transport layer, and the quantum dots with the long-chain ligand in sequence. After the quantum dots the long-chain ligands are prepared, underlying quantum dots with long-chain ligands are subjected to solid-state ligand exchange with short-chain ligands (specifically, ZnCl₂ dissolved in ethanol is dropwise applied onto the quantum dots with the long-chain ligands after post-baking for 10 min at 100° C. in a nitrogen environment, and is subjected to standing for 2 min; subsequently, spin coating is carried out at a certain speed to form a film; ethanol is spin coated on a quantum dot layer subjected to ligand exchange to remove excess ZnCl₂), such that the quantum dots in contact with the hole injection layer become quantum dots with short-chain ligands (short-chain ligands include, but are not limited to, thiol, dithiol, mercapto acid, mercaptoalcohol, mercaptoamine, halogen ligands, etc.). Then, spin coating is carried out to prepare an electron transport layer. Cathode metal is subjected to evaporation, wherein the cathode may employ an Al layer or the like, which is about 500-1000 nm. Encapsulation is carried out after evaporation to complete the preparation of the QLED device. This solid-state ligand exchange method does not form quantum dots with long and short-chain ligands having distinct boundaries, and the extent of ligand exchange gradually decreases as the short-chain ligands permeates from top to bottom over the quantum dots with the long-chain ligand.

In some embodiments, taking a quantum dot light-emitting device shown in FIG. 7 as an example, a manufacturing method of the quantum dot light-emitting device provided by the embodiment of the present disclosure is illustrated as follows.

For example, in an example that the quantum dot light-emitting device shown in FIG. 7 is a multi-electron upright QLED device system, the quantum dot light-emitting device specifically includes a base substrate 1, an anode (a first electrode layer 21), a hole injection layer 41, a hole transport layer 42, a second quantum dot light-emitting layer 32 with a short-chain second ligand, a first quantum dot light-emitting layer 31 with a long-chain first ligand, an electron transport layer 43, a cathode (a second electrode layer 22), which are sequentially located on one side of the base substrate 1, and a preparation process of the device is as follows:
1. cleaning the base substrate containing the first electrode 21 (specifically indium tin oxide, ITO);
2. depositing the hole injection layer 41 on the base substrate by a spin coating method, wherein the specific materials may be poly 3,4-ethylenedioxythiophene, PEDOT:PSS;
3. spin coating and depositing the hole transport layer 42 on the hole injection layer 41;
4. preparing, by spin coating, a quantum dot film layer with a long-chain ligand (e.g., an oleic acid ligand) on the hole transport layer 42;
5. carrying out solid-state ligand exchange on underlying quantum dots with long-chain ligand using short-chain ligands, making a quantum dot film layer in contact with the hole transport layer 42 become a quantum dot film layer with a short-chain ligand, and taking the film layer as the second quantum dot light-emitting layer 32;
6. cleaning excess short-chain ligands with ethanol to remove excess short-chain ligand from the surfaces of the quantum dots with a short-chain ligand;
7. spin coating quantum dots with long-chain ligands on short-chain ligands, to serve as the first quantum dot light-emitting layer 31;
8. spin coating an electron transport layer material (e.g., ZnMgO) on the quantum dots with long-chain ligands, to serve as the electron transport layer 43; and
9. evaporating the cathode to serve as the second electrode layer 22, and carrying out encapsulation to complete the preparation of the whole device.

Embodiments of the present disclosure may have the following beneficial effects: The light-emitting layer group includes a first quantum dot light-emitting layer and a second quantum dot light-emitting layer disposed in a lamination manner. The chain length of a first ligand of the first quantum dot light-emitting layer is greater than the chain length of a second ligand of the second quantum dot light-emitting layer. The first quantum dot light-emitting layer is located on one surface of the second quantum dot light-emitting layer 32 facing a multi-carrier entry side, that is, electrons and holes can be blocked from injection using the characteristic of poor electron or hole transport performance of the long-chain ligand by applying quantum dots with long-chain ligands and short-chain ligands respectively in the light-emitting device, and then a first quantum dot light-emitting layer with a long-chain ligand may be disposed on the side where more carriers (electrons or holes) are injected, reducing the injection of carriers on this side. Meanwhile, in order to avoid blocking the injection of carriers on the other side by the first quantum dot light-emitting layer with the long-chain ligand, a second quantum dot light-emitting layer with a short-chain ligand may be provided, and the second quantum dot light-emitting layer with the short-chain ligand facilitates injection of carriers, so that the first quantum dot light-emitting layer and the second quantum dot light-emitting layer can be used to block the injection at the side where more carriers are injected, and to increase the injection at the side where fewer carriers are injected, so as to regulate the injection of electrons and holes, thereby achieving injection balance of carriers.

It will be apparent to those skilled in the art that various modifications and variations can be made to embodiments of the present disclosure without departing from the spirit and scope of the embodiments of the present disclosure. Thus, if these modifications and variations of the embodiments of the present disclosure fall within the scope of the claims of the present disclosure and their equivalent technologies, the present disclosure is also intended to contain these modifications and variations.

1. A quantum dot light-emitting device, comprising:
a base substrate;
a first electrode layer on one side of the base substrate;
a second electrode layer on one side facing away from the base substrate, of the first electrode layer;
a light-emitting layer group between the first electrode layer and the second electrode layer, and comprising a first quantum dot light-emitting layer and a second quantum dot light-emitting layer disposed in a lamination manner, wherein the first quantum dot light-emitting layer comprises a first quantum dot body, and a first ligand connected to the first quantum dot body; the second quantum dot light-emitting layer comprises a second quantum dot body, and a second ligand connected to the second quantum dot body; a chain length of the first ligand is greater than a chain length of the second ligand, and a difference between the chain length of the first ligand and the chain length of the second ligand is greater than a first preset value; a difference between a quantity of carriers arriving at the light-emitting layer group from the first electrode layer and a quantity of carriers arriving at the light-emitting layer group from the second electrode layer is greater than a second preset value; and one side of the light-emitting layer group with a great quantity of incoming carriers serves as a multi-carrier entry side, and the first quantum dot light-emitting layer is on one side facing the multi-carrier entry side, of the second quantum dot light-emitting layer.

2. The quantum dot light-emitting device of claim 1, wherein the first ligand comprises one of:
trioctylphosphine,
tributylphosphine,
oleic acid,
stearic acid,
oleylamine,
long-chain alkylamine,
long-chain alkylphosphine, or
long-chain alkylphosphonic acid.

3. The quantum dot light-emitting device of claim 2, wherein the second ligand comprises one of:
thiol,
dithiol,
mercapto acid,
mercaptoalcohol,
mercaptoamine, or
a halogen ligand.

4. The quantum dot light-emitting device of claim 1, wherein a thickness of the first quantum dot light-emitting layer is in positive correlation with the second preset value.

5. The quantum dot light-emitting device of claim 1, wherein the quantity of carriers arriving at the light-emitting layer group from the first electrode layer is greater than the quantity of carriers arriving at the light-emitting layer group from the second electrode layer, and one side facing the first electrode layer, of the light-emitting layer group serves the multi-carrier entry side; and
the first quantum dot light-emitting layer is on one side facing the first electrode layer, of the second quantum dot light-emitting layer.

6. The quantum dot light-emitting device of claim 1, wherein the quantity of carriers arriving at the light-emitting layer group from the first electrode layer is less than the quantity of carriers arriving at the light-emitting layer group from the second electrode layer, and one side facing the second electrode layer, of the light-emitting layer group serves as the multi-carrier entry side; and
the first quantum dot light-emitting layer is on one side of the second quantum dot light-emitting layer facing the second electrode layer.

7. The quantum dot light-emitting device of claim 1, wherein the first quantum dot body is identical to the second quantum dot body.

8. The quantum dot light-emitting device of claim 1, wherein the first quantum dot light-emitting layer comprises at least one first sub-quantum dot light-emitting layer disposed in a lamination manner, and first ligands of first sub-quantum dot light-emitting layers are the same, and first quantum dot bodies of the first sub-quantum dot light-emitting layers are the same; and
the second quantum dot light-emitting layer comprises at least one second sub-quantum dot light-emitting layer disposed in a lamination manner, and second ligands of second sub-quantum dot light-emitting layers are the same, and second quantum dot bodies of the second sub-quantum dot light-emitting layers are the same.

9. A display apparatus, comprising a quantum dot light-emitting device, wherein the quantum dot light-emitting device comprises:
a base substrate;
a first electrode layer on one side of the base substrate;
a second electrode layer on one side facing away from the base substrate, of the first electrode layer;
a light-emitting layer group between the first electrode layer and the second electrode layer, and comprising a first quantum dot light-emitting layer and a second quantum dot light-emitting layer disposed in a lamination manner, wherein the first quantum dot light-emitting layer comprises a first quantum dot body, and a first ligand connected to the first quantum dot body; the second quantum dot light-emitting layer comprises a second quantum dot body, and a second ligand connected to the second quantum dot body; a chain length of the first ligand is greater than a chain length of the second ligand, and a difference between the chain length of the first ligand and the chain length of the second ligand is greater than a first preset value; a difference between a quantity of carriers arriving at the light-emitting layer group from the first electrode layer and a quantity of carriers arriving at the light-emitting layer group from the second electrode layer is greater than a second preset value; and one side of the light-emitting layer group with a great quantity of incoming carriers serves as a multi-carrier entry side, and the first quantum dot light-emitting layer is on one side facing the multi-carrier entry side, of the second quantum dot light-emitting layer.

10. A method for manufacturing the quantum dot light-emitting device of claim 1, comprising:
forming the first electrode layer on one side of the base substrate;
forming the light-emitting layer group on one side facing away from the base substrate of the first electrode layer; and
forming a second electrode layer on one side facing away from the first electrode layer, of the light-emitting layer group.

11. The method of claim 10, wherein in response to the quantity of carriers arriving at the light-emitting layer group from the first electrode layer being greater than the quantity of carriers arriving at the light-emitting layer group from the second electrode layer, the forming the light-emitting layer group on one side facing away from the base substrate, of the first electrode layer comprises:
forming the first quantum dot light-emitting layer on one side facing away from the base substrate, of the first electrode layer; and
forming the second quantum dot light-emitting layer on one side facing away from the first electrode layer, of the first quantum dot light-emitting layer.

12. The method of claim 11, wherein the forming the first quantum dot light-emitting layer on one side facing away from the base substrate, of the first electrode layer, and forming the second quantum dot light-emitting layer on one side facing away from the first electrode layer, of the first quantum dot light-emitting layer, comprise:
forming a first quantum dot solution in which the first ligand modifies the first quantum dot body, and a second quantum dot solution in which a third ligand modifies the second quantum dot body;
replacing, in a solution state, the third ligand in the second quantum dot solution with a second ligand by a replacement reaction to form a third quantum dot solution in which the second ligand modifies the second quantum dot body, wherein a chain length of the third ligand is greater than the chain length of the second ligand;
overlaying the first quantum dot solution on one side facing away from the base substrate, of the first electrode layer to serve as the first quantum dot light-emitting layer; and
overlaying the third quantum dot solution on one side facing away from the first electrode layer, of the first quantum dot light-emitting layer to serve as the second quantum dot light-emitting layer.

13. The manufacturing method of claim 11, wherein the forming the first quantum dot light-emitting layer on one side facing away from the base substrate, of the first electrode layer, and forming the second quantum dot light-emitting layer on one side facing away from the first electrode layer, of the first quantum dot light-emitting layer, comprise:
forming a first quantum dot solution in which the first ligand modifies the first quantum dot body, and a second quantum dot solution in which a third ligand modifies the second quantum dot body;
overlaying the first quantum dot solution on one side facing away from the base substrate, of the first electrode layer to serve as the first quantum dot light-emitting layer; and
overlaying the second quantum dot solution on one side facing away from the first electrode layer, of the first quantum dot light-emitting layer, and overlaying a solution containing the second ligand after film formation to replace the third ligand with the second ligand to serve as the second quantum dot light-emitting layer.

14. The manufacturing method of claim 10, wherein in response to the quantity of carriers arriving at the light-emitting layer group from the first electrode layer being less than the quantity of carriers arriving at the light-emitting layer group from the second electrode layer, the forming the light-emitting layer group on one side facing away from the base substrate, of the first electrode layer comprises:
forming the second quantum dot light-emitting layer on one side facing away from the base substrate, of the first electrode layer; and
forming the first quantum dot light-emitting layer on one side facing away from the first electrode layer, of the second quantum dot light-emitting layer.

15. The manufacturing method of claim 14, wherein the forming the second quantum dot light-emitting layer on one side facing away from the base substrate, of the first electrode layer; and forming the first quantum dot light-emitting layer on one side facing away from the first electrode layer, of the second quantum dot light-emitting layer comprise:
forming the first quantum dot solution in which the first ligand modifies the first quantum dot body, and a second quantum dot solution in which a third ligand modifies the second quantum dot body;
overlaying the second quantum dot solution on one side facing away from the base substrate, of the first electrode layer and overlaying a solution containing the second ligand after film formation to replace the third ligand with the second ligand to serve as the second quantum dot light-emitting layer; and
overlaying the first quantum dot solution on one side facing away from the first electrode layer, of the second quantum dot light-emitting layer.

16. The display apparatus of claim 9, wherein the first ligand comprises one of:
trioctylphosphine,
tributylphosphine,
oleic acid,
stearic acid,
oleylamine,
long-chain alkylamine,
long-chain alkylphosphine, or
long-chain alkylphosphonic acid.

17. The display apparatus of claim 16, wherein the second ligand comprises one of:
thiol,
dithiol,
mercapto acid,
mercaptoalcohol,
mercaptoamine, or
a halogen ligand.

18. The display apparatus of claim 9, wherein a thickness of the first quantum dot light-emitting layer is in positive correlation with the second preset value.

19. The display apparatus of claim 9, wherein the quantity of carriers arriving at the light-emitting layer group from the first electrode layer is greater than the quantity of carriers arriving at the light-emitting layer group from the second electrode layer, and one side facing the first electrode layer, of the light-emitting layer group serves the multi-carrier entry side; and
the first quantum dot light-emitting layer is on one side facing the first electrode layer, of the second quantum dot light-emitting layer.

20. The display apparatus of claim 9, wherein the quantity of carriers arriving at the light-emitting layer group from the first electrode layer is less than the quantity of carriers arriving at the light-emitting layer group from the second electrode layer, and one side facing the second electrode layer, of the light-emitting layer group serves as the multi-carrier entry side; and
the first quantum dot light-emitting layer is on one side of the second quantum dot light-emitting layer facing the second electrode layer.
